(19) United States
(12) Patent Application Publication
(10) Pub. No.: US 2025/0343380 A1
(43) Pub. Date: Nov. 6, 2025

(54) GROUNDING CLIP FOR REDUCED INTERFERENCE FROM HDMI RECEPTACLES

(71) Applicant: Google LLC, Mountain View, CA (US)

(72) Inventors: Weichih Chen, Taiwan (TW); Hou-En Chen, Taiwan (TW); Ting-Yu Guu, Hsinchu County (TW); Hsiang-Hao Chang, Taiwan (TW)

(73) Assignee: Google LLC, Mountain View, CA (US)

(21) Appl. No.: 18/656,288

(22) Filed: May 6, 2024

(51) Int. Cl. H01R 13/6594; H05K 1/18; H05K 3/32

(52) U.S. Cl. CPC H01R 13/6594; H05K 1/18; H05K 3/325; H05K 2201/10189; H05K 2201/10386

(57) ABSTRACT

A clip for increased grounding of a high-definition multimedia interface (HDMI) receptacle includes a lower jaw structure, an upper jaw structure opposite the lower jaw structure, a compression hinge that connects the lower jaw structure to the upper jaw structure and clamps a PCB between the lower jaw structure at a grounding pad on a first surface of the PCB, and the upper jaw structure at an HDMI receptacle mating area on a second surface of the PCB opposite the first surface, a prong structure, and an expansion hinge that connects the prong structure to the upper jaw structure opposite the compression hinge and presses the prong structure against an exterior surface of an HDMI receptacle installed on the first surface of the PCB.

### BACKGROUND

With the rise of streaming platforms and services, content is often obtained by a streaming device via one or more wired and/or wireless connections. Such streaming devices often output the content to a display using a High-Definition Multimedia Interface (HDMI). As data transmission rates associated with HDMI continue to increase, so too does the ability to provide higher quality video and audio content. However, while increased data transmission rates of HDMI may allow streaming devices to provide better video quality as an output, additional considerations may be required when integrating HDMI into wireless streaming devices.

### SUMMARY

In some embodiments, a high-definition multimedia interface (HDMI) assembly is provided. The assembly may include a printed circuit board (PCB) comprising a first surface, a second surface opposite the first surface, an HDMI receptacle mating area on the first surface at an edge of the PCB, and a grounding pad on the second surface opposite the HDMI receptacle mating area. The assembly may further include an HDMI receptacle installed on the first surface of the PCB at the HDMI receptacle mating area and having an exterior surface opposite the first surface of the PCB. The assembly may further include a grounding clip. The grounding clip may include: a lower jaw structure; an upper jaw structure opposite the lower jaw structure; a compression hinge that connects the lower jaw structure to the upper jaw structure and clamps the PCB between the lower jaw structure at the grounding pad and the upper jaw structure at the HDMI receptacle mating area; a prong structure; and an expansion hinge that connects the prong structure to the upper jaw structure opposite the compression hinge and presses the prong structure against the exterior surface of the HDMI receptacle.

In some embodiments, the grounding clip is a single piece of conductive material that forms each of the lower jaw structure, the compression hinge, the upper jaw structure, the expansion hinge, and the prong structure. In some embodiments, the single piece of conductive material comprises a planar strip of metal.

In some embodiments, the compression hinge separates a first end of the upper jaw structure from a first end of the lower jaw structure at the compression hinge by a first distance, and the upper jaw structure and the lower jaw structure extend from the compression hinge toward each other in a first direction so that a second end of the lower jaw structure opposite the first end of the lower jaw structure is separated from a second end of the upper jaw structure opposite the first end of the upper jaw structure by a second distance that is less than the first distance. In some embodiments, the first end of the upper jaw structure connects with a first end of the compression hinge at a right angle and the first end of the lower jaw structure connects with a second end of the compression hinge opposite the first end of the compression hinge. In some embodiments, the expansion hinge connects the prong structure to the upper jaw structure at an acute angle.

In some embodiments, the grounding clip provides a continuous electrical connection between the exterior surface of the HDMI receptable and a ground plane of the PCB via the grounding pad on the second surface of the PCB. In some embodiments, the HDMI receptacle forms an opening through the exterior surface surrounding a spring finger that is depressed toward the first surface of the PCB by an HDMI plug inserted within an interior space formed by the HDMI receptacle; and the prong structure comprises a cutout at an end of the prong structure opposite the expansion hinge, the cutout being aligned with the opening through the exterior surface of the HDMI receptacle. In some embodiments, the PCB further comprises a secondary grounding pad on the first surface of the PCB within the HDMI receptacle mating area; and a force applied to the prong structure toward the upper jaw structure causes the expansion hinge to press the upper jaw structure against the secondary grounding pad.

In some embodiments, a method of manufacturing a video device with reduced electromagnetic interference is provided. The method may include obtaining a printed circuit board (PCB) comprising a first surface, a second surface opposite the first surface, an HDMI receptacle mating area on the first surface at an edge of the PCB, and a grounding pad on the second surface opposite the HDMI receptacle mating area. The method may further include installing an HDMI receptacle on the first surface of the PCB at the HDMI receptacle mating area, wherein the HDMI receptacle comprises an exterior surface opposite the first surface of the PCB. The method may further include electrically connecting the exterior surface of the HDMI receptacle to the grounding pad of the PCB with a grounding clip by inserting the edge of the PCB between a lower jaw structure of the grounding clip and an upper jaw structure of the grounding clip opposite the lower jaw structure so that the second surface of the PCB faces the lower jaw structure and the first surface of the PCB faces the upper jaw structure. In some embodiments, a compression hinge connecting the lower jaw structure to the upper jaw structure clamps the PCB between the lower jaw structure at the grounding pad and the upper jaw structure at the HDMI receptacle mating area. Electrically connecting the exterior surface of the HDMI receptacle to the grounding pad may further include inserting, between the first surface of the PCB and the exterior surface of the HDMI receptacle, the upper jaw structure, a prong structure of the grounding clip, and an expansion hinge of the grounding clip that connects the prong structure to the upper jaw structure opposite the compression hinge and presses the prong structure against the exterior surface of the HDMI receptacle.

In some embodiments, the grounding clip is a single piece of conductive material that forms each of the lower jaw structure, the compression hinge, the upper jaw structure, the expansion hinge, and the prong structure. In some embodiments, the single piece of conductive material comprises a planar strip of metal. In some embodiments, the planar strip of metal comprises a first end and a second end separated by a middle portion and the method further includes forming the grounding clip. Forming the grounding clip may include bending the first end of the planar strip of metal in a first direction with respect to the middle portion by at least 180 degrees to form the compression hinge; and bending the second end of the planar strip of metal in a second direction opposite the first direction by at least 90 degrees and less than 180 degrees to form the expansion hinge.

In some embodiments, the edge of the PCB is inserted between the lower jaw structure and the upper jaw structure simultaneously with insertion of the upper jaw structure, the prong structure, and the expansion hinge between the first surface of the PCB and the exterior surface of the HDMI receptacle. In some embodiments, the grounding clip provides a continuous electrical connection between the exterior surface of the HDMI receptable and a ground plane of the PCB via the grounding pad on the second surface of the PCB.

In some embodiments, the HDMI receptacle forms an opening through the exterior surface surrounding a spring finger that is depressed toward the first surface of the PCB by an HDMI plug inserted within an interior space formed by the HDMI receptacle; the prong structure comprises a cutout at an end of the prong structure opposite the expansion hinge; and the upper jaw structure, the prong structure, and the expansion hinge are inserted between the first surface of the PCB and the exterior surface of the HDMI receptacle until the cutout is aligned with the opening through the exterior surface of the HDMI receptacle. In some embodiments, the PCB further comprises a secondary grounding pad on the first surface of the PCB within the HDMI receptacle mating area and a force applied to the prong structure toward the upper jaw structure by the exterior surface of the HDMI receptacle causes the expansion hinge to press the upper jaw structure against the secondary grounding pad.

In some embodiments, a clip for increased grounding of an HDMI receptacle is provided. The clip may include: a lower jaw structure; an upper jaw structure opposite the lower jaw structure; a compression hinge that connects the lower jaw structure to the upper jaw structure and clamps a PCB between the lower jaw structure at a grounding pad on a first surface of the PCB, and the upper jaw structure at an HDMI receptacle mating area on a second surface of the PCB opposite the first surface; a prong structure; and an expansion hinge that connects the prong structure to the upper jaw structure opposite the compression hinge and presses the prong structure against an exterior surface of an HDMI receptacle installed on the first surface of the PCB.

In some embodiments, the lower jaw structure, the compression hinge, the upper jaw structure, the expansion hinge, and the prong structure are a single piece of planar conductive material. In some embodiments, the compression hinge separates a first end of the upper jaw structure from a first end of the lower jaw structure at the compression hinge by a first distance; the upper jaw structure and the lower jaw structure extend from the compression hinge toward each other in a first direction so that a second end of the lower jaw structure opposite the first end of the lower jaw structure is separated from a second end of the upper jaw structure opposite the first end of the upper jaw structure by a second distance that is less than the first distance; and the expansion hinge connects the prong structure to the upper jaw structure at an acute angle opening in a second direction opposite the first direction.

### BRIEF DESCRIPTION OF THE DRAWINGS

A further understanding of the nature and advantages of various embodiments may be realized by reference to the following figures. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 illustrates a front top perspective view of an embodiment of a grounding clip.

FIG. 2 illustrates a front view of an embodiment of the grounding clip.

FIG. 3 illustrates a back view of an embodiment of the grounding clip.

FIG. 4 illustrates a top view of an embodiment of the grounding clip.

FIG. 5 illustrates a bottom view of an embodiment of the grounding clip.

FIG. 6 illustrates a side view of an embodiment of the grounding clip.

FIG. 7 illustrates an expanded view of an embodiment of an HDMI assembly including a PCB and a grounding clip from above.

FIG. 8 illustrates an expanded view of an embodiment of an HDMI assembly including a PCB, a grounding device, and an HDMI receptacle from below.

FIG. 9 illustrates an assembled view of an embodiment of an HDMI assembly including a PCB, a grounding device, and an HDMI receptacle from below.

FIG. 10 illustrates a flowchart of an embodiment of a method for manufacturing a video device with reduced electromagnetic interference.

### DETAILED DESCRIPTION

Increased data transmission rates of HDMI may allow streaming devices to provide better video quality as an output but may also cause a correlated deterioration in wireless data transmission rates, thereby limiting streaming devices from providing the better video quality without a wired connection. Within HDMI enabled streaming devices, the HDMI receptacle itself may be a source of electromagnetic interference (EMI). EMI associated with an HDMI receptacle arises from the high-frequency signals transmitted through the physical interface, which can generate unwanted electromagnetic radiation that interferes with the operation of nearby electronic components and devices. For example, this interference may result in decreased sensitivity and throughput for wireless communication devices, such as Wi-Fi® or Bluetooth® radios.

Embodiments described herein address these and other challenges associated with reducing EMI from off-the-shelf HDMI receptacles using a grounding clip that provides a pathway for noise current to be conducted from the radiating surfaces of the HDMI receptacle to a grounded connection. Specifically, a grounding clip as detailed herein can be installed with an upper portion of the clip being inserted between a printed circuit board (PCB) and the HDMI receptacle, and the PCB being inserted within an opening formed by the lower portion of the clip. Once installed, a prong structure at the end of the upper portion of the clip may make contact with the bottom side of the HDMI receptacle, while a grounding portion of the lower portion of the clip makes contact with a ground pad on the surface of the PCB, thereby providing a low-resistance path for the noise current to flow from the HDMI receptacle to a ground plane of the PCB.

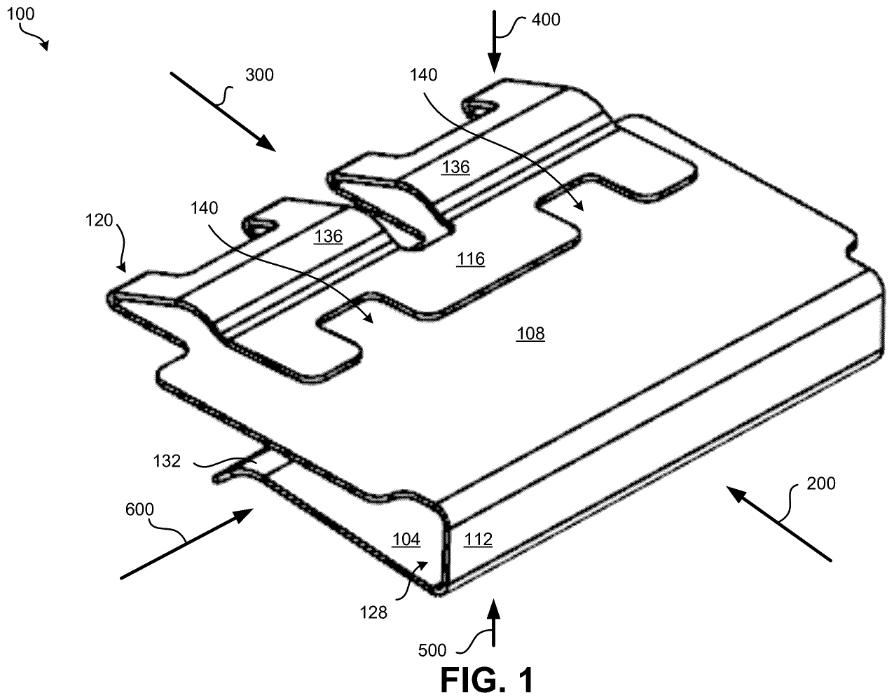

FIG. 1 illustrates a perspective view of an embodiment of a grounding clip 100 from above. As illustrated, grounding clip 100 includes a single piece of conductive material that forms each of lower jaw structure 104, upper jaw structure 108, compression hinge 112 that connects lower jaw structure 104 to upper jaw structure 108, prong structure 116, and expansion hinge 120 that connects prong structure 116 to upper jaw structure 108 opposite compression hinge 112. For example, a single planar strip of conductive metal, such as silver, copper, gold, aluminum, brass, or the like, may be cast, rolled, extruded, or otherwise shaped to form the final structure of grounding clip 100. Additionally, or alternatively, grounding clip 100 may include multiple pieces of conductive materials joined together. For example, each of lower jaw structure 104, upper jaw structure 108, compression hinge 112, prong structure 116, and/or expansion hinge 120 may be separate pieces of conductive material joined together (e.g., by welding) to form the structure of grounding clip 100.

Grounding clip 100 may have an overall length extending from an end of lower jaw structure 104 opposite compression hinge 112, to an end of prong structure 116 opposite expansion hinge 120, and including the lengths of lower jaw structure 104, compression hinge 112, upper jaw structure 108, expansion hinge 120, and prong structure 116. Grounding clip 100 may have various widths along its length. For example, the width of grounding clip 100 along lower jaw structure 104, compression hinge 112, and upper jaw structure 108 may be less than or equal to approximately 14 millimeters. In some embodiments, the maximum width of grounding clip 100 is selected based on one or more dimensions of an HDMI receptacle. For example, the maximum width of grounding clip 100 may be selected to be less than or equal to a width of an HDMI receptacle. Grounding clip 100 may have a uniform thickness along its length and width. In some embodiments, the thickness of grounding clip 100 is selected based on the hardness of the material, or materials, used to form grounding clip 100. For example, based on the hardness of the material, the thickness of grounding clip 100 may be selected to resist deformation when a force is applied to any portion.

Compression hinge 112 may connect lower jaw structure 104 to upper jaw structure 108 such that lower jaw structure 104 and upper jaw structure 108 extend away from compression hinge 112 toward each other in approximately the same direction to form opening 128. Opening 128 may be shaped to receive a planar item (not shown), such as an edge of a PCB. As illustrated, compression hinge 112 may include a flat portion of conductive material that meets upper jaw structure 108 at a first angle within opening 128 and that meets lower jaw structure 104 at a second angle within opening 128. In some embodiments, the first and second angles are selected such that their summation is less than 180 degrees. For example, the first angle may be approximately 90 degrees and the second angle may be less than 90 degrees. Additionally, or alternatively, compression hinge 112 may include a rounded portion of conductive material.

In some embodiments, the length, and/or diameter, of compression hinge 112 is selected to accommodate an item having a predefined thickness within opening 128. For example, the length, and/or diameter, may be greater than the thickness of a PCB. When inserted within opening 128, the thickness and/or hardness of material that forms compression hinge 112, as well as the angles between compression hinge 112, upper jaw structure 108, and lower jaw structure 104, may clamp a PCB between lower jaw structure 104 and upper jaw structure 108.

Lower jaw structure 104 may include grounding portion 132 opposite compression hinge 112. In some embodiments, the length of lower jaw structure 104, and/or the angle at which lower jaw structure 104 extends from compression hinge 112, are selected such that grounding portion 132 presses against a grounding pad on a first surface of a PCB inserted within opening 128, electrically connecting grounding clip 100 to the grounding pad and/or ground plane of the PCB. Additionally, or alternatively, upper jaw structure 108 may make contact with a grounding pad on an opposite surface of the PCB inserted within opening 128. The force applied by compression hinge 112 to clamp the PCB between upper jaw structure 108 and lower jaw structure 104 may ensure that the electrical connection between grounding clip 100 and the PCB are maintained.

Expansion hinge 120 may connect upper jaw structure 108 to prong structure 116 such that upper jaw structure 108 and prong structure 116 extend away from expansion hinge 120, and each other, in approximately the same direction. As illustrated, expansion hinge 120 may include a rounded portion of conductive material that connects upper jaw structure 108 to prong structure 116 at an acute angle. The thickness and/or hardness of material that forms expansion hinge 120, as well as the angle between upper jaw structure 108 and prong structure 116, may be selected to resist compression of prong structure 116 toward upper jaw structure 108.

Prong structure 116 may include one or more bent or curved portions along the length of conductive material between expansion hinge 120 and the end of prong structure 116 opposite expansion hinge 120. For example, and as illustrated, prong structure 116 may include HDMI grounding portion 136 located at a midpoint of prong structure 116. HDMI grounding portion 136 may be located at a point along the length of prong structure 116 that is furthest from upper jaw structure 108. In some embodiments, HDMI grounding portion 136 includes the end of prong structure 116.

Upper jaw structure 108, expansion hinge 120, and prong structure 116 may be configured to be inserted between a surface of a PCB and an electrical component mounted to the surface of the PCB such that prong structure 116 is compressed toward upper jaw structure 108. The length of prong structure 116, and/or the angle between upper jaw structure 108 and prong structure 116, may be selected so that the vertical distance from the surface of upper jaw structure 108 to HDMI grounding portion 136 is greater than the distance between the surface of a PCB and an exterior surface of the electrical component that is opposite the surface of the PCB. In some embodiments, the electrical component is an HDMI receptacle, as described further herein. When upper jaw structure 108, expansion hinge 120, and prong structure 116 are inserted between a PCB an electrical component, expansion hinge 120 may press HDMI grounding portion 136 against a metal surface of the electrical component. When compressed between a PCB and an electrical component, expansion hinge 120 may also press upper jaw structure 108 against a ground pad of the PCB.

As illustrated, the edge of prong structure 116 opposite expansion hinge 120 may form one or more cutouts 140 where the edge of prong structure 116 is recessed toward expansion hinge 120. The one or more cutouts 140 may be located along the edge of prong structure 116 at points that align with moving parts of an electrical component installed on a PCB. For example, in the case of an HDMI receptacle, the one or more cutouts 140 may be aligned with openings through an exterior surface of the HDMI receptacle that surround spring fingers, thereby allowing the spring fingers to be depressed toward the surface of the PCB by an HDMI plug inserted within an interior space formed by the HDMI receptacle without making contact with prong structure 116.

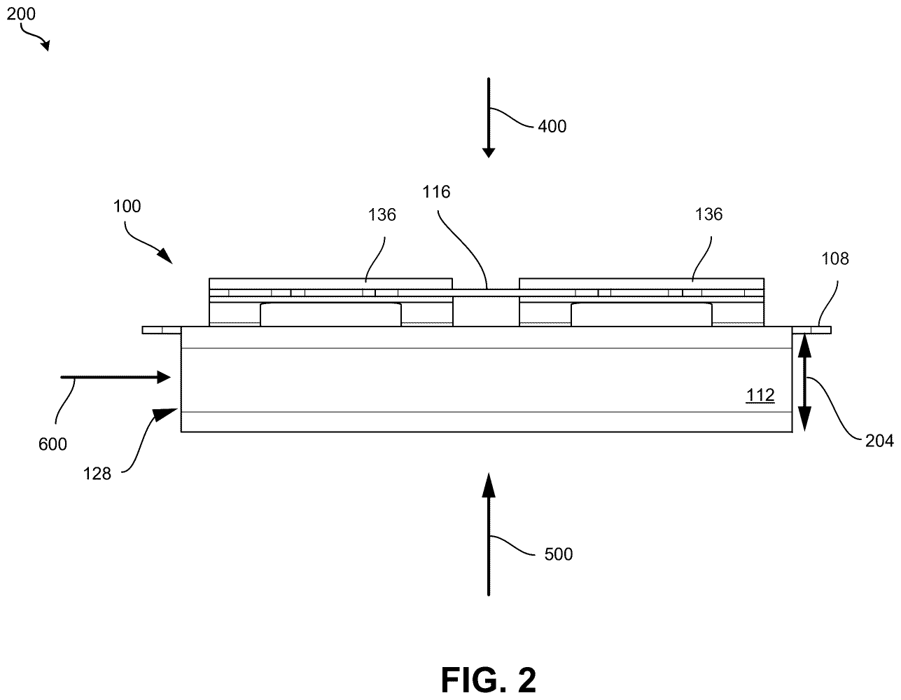

FIG. 1 illustrates relative perspectives for a front view 200, a back view 300, a top view 400, a bottom view 500, and a side view 600, to be described in detail with respect to FIGS. 2-6 below. One having ordinary skill in the art upon reading the present disclosure would appreciate that the HDMI grounding device 100 may have more or less sides than the exemplary embodiment shown in FIGS. 1-6.

FIG. 2 illustrates front view 200 of grounding clip 100 described above. As illustrated in front view 200, grounding clip 100 includes first length 204 of material that forms compression hinge 112. As described above, first length 204 may be selected based on the thickness of a PCB. For example, first length 204 may be selected such that opening 128 can receive an edge of a PCB. In some embodiments, first length 204 is approximately 2 millimeters.

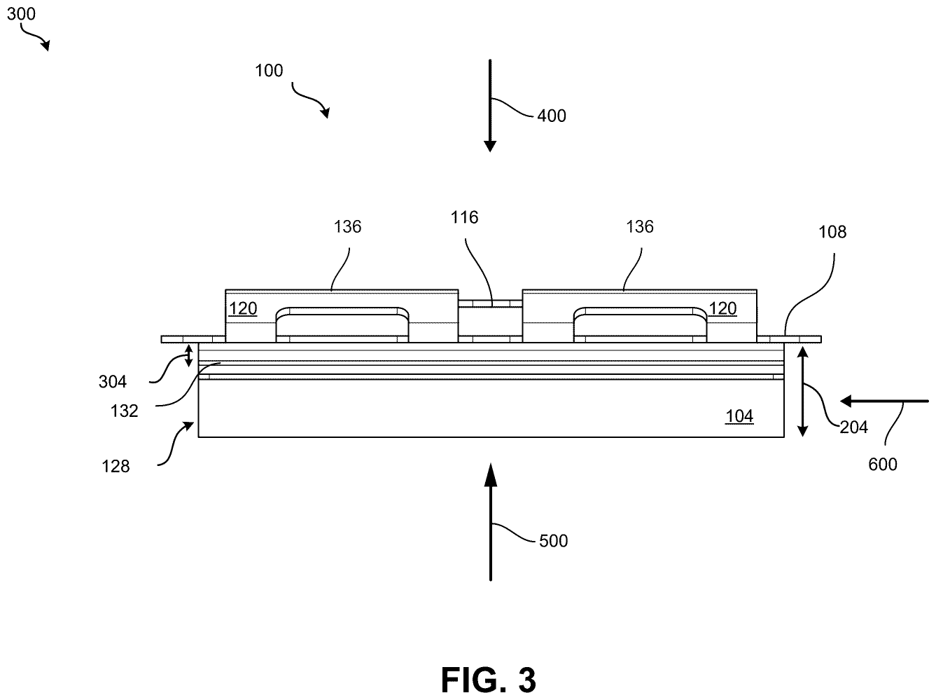

FIG. 3 illustrates back view 300 of grounding clip 100 described above. As illustrated in back view 300, compression hinge 112 connects upper jaw structure 108 to lower jaw structure 104 such that opening 128 is formed with vertical distance 304 between the ends of upper jaw structure 108 and lower jaw structure 104 opposite compression hinge 112. As further illustrated, compression hinge 112 may connect upper jaw structure 108 to lower jaw structure 104 such that vertical distance 304 is less than first length 204 of the material that forms compression hinge 112, as shown in front view 200 described above.

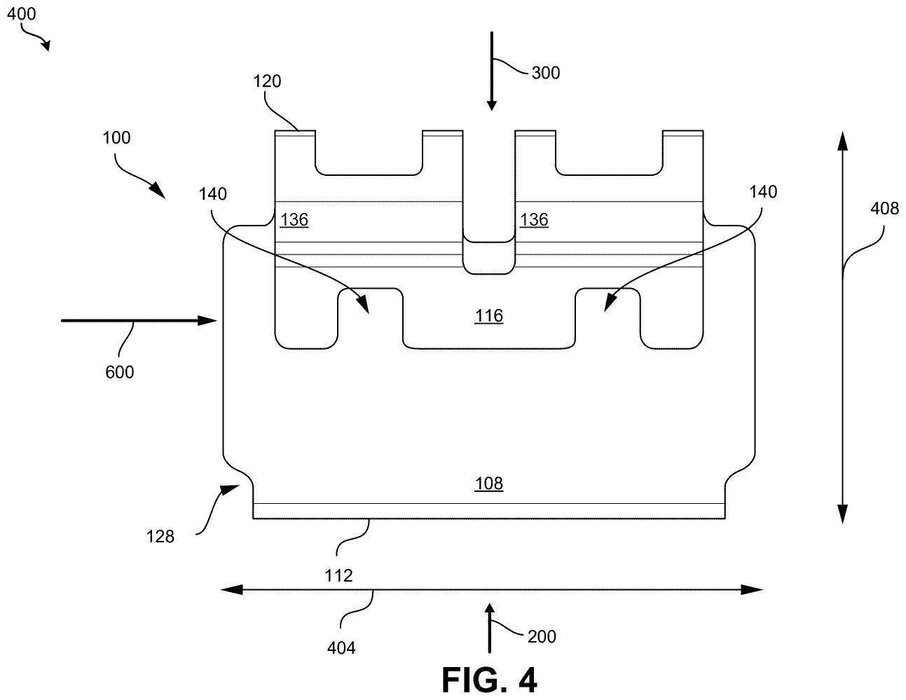

FIG. 4 illustrates top view 400 of grounding clip 100 described above. As illustrated in top view 400, grounding clip 100 has maximum width 404 along length 408 of upper jaw structure 108. As described above, maximum width 404 and length 408 may be selected to fit within the footprint of an electrical component, such as an HDMI receptacle, when installed on a PCB. For example, maximum width 404 may be less than or equal to the internal distance between support structures on either side of an HDMI receptacle, as described further herein. In some embodiments, maximum width 404 is approximately 14 millimeters. As another example, length 408 may be less than or equal to the distance from an edge of a PCB to through-holes on the PCB that receive the pins of an HDMI receptacle. Additionally, or alternatively, length 408 may be less than or equal to the distance from the front of an HDMI receptacle to the pins at the back of the HDMI receptacle. In some embodiments, length 408 is approximately 9 millimeters.

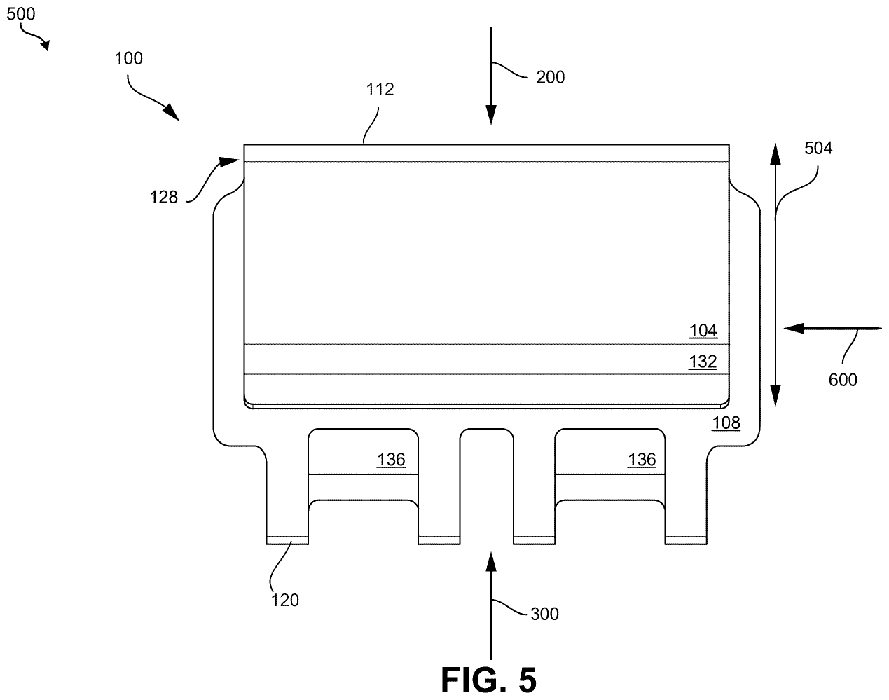

FIG. 5 illustrates bottom view 500 of grounding clip 100 described above. As illustrated in bottom view 500, lower jaw structure 104 includes length 504 of grounding clip 100. As described above, length 504 may be selected so that grounding portion 132 is aligned with a ground pad on a surface of a PCB when the edge of the PCB is fully inserted within opening 128.

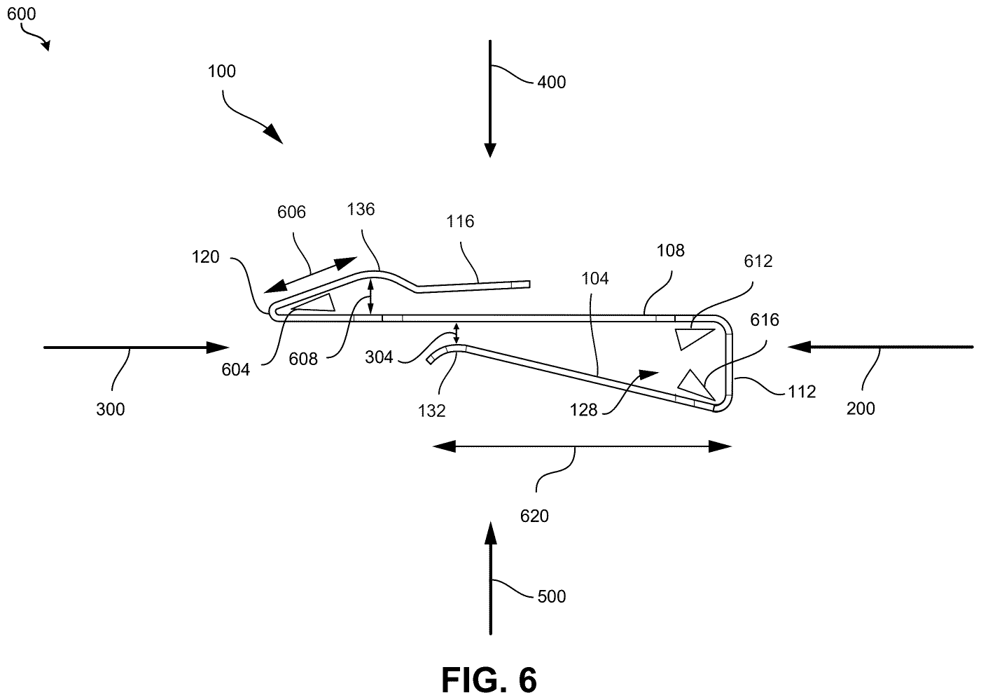

FIG. 6 illustrates side view 600 of grounding clip 100 described above. As illustrated in side view 600, expansion hinge 120 connects upper jaw structure 108 to prong structure 116 at first angle 604. HDMI grounding portion 136 may be separated from expansion hinge 120 by first distance 606. HDMI grounding portion 136 may be vertically separated from a surface of upper jaw structure 108 by vertical distance 608. As described above, first angle 604 and/or first distance 606 may be selected based on the distance from a surface of a PCB to an opposite surface of an electrical component installed on the PCB, between which upper jaw structure 108, expansion hinge 120, and prong structure 116 may be inserted. For example, first angle 604 and/or first distance 606 may be selected so that vertical distance 608 is greater than the distance from the surface of the PCB to the opposite surface of the electrical component.

As further illustrated, compression hinge 112 meets upper jaw structure 108 and lower jaw structure 104 at second angle 612 and third angle 616, respectively. Grounding portion 132 of lower jaw structure 104 may be separated from third angle 616 by second distance 620. As described above, second distance 620 may be selected based on a location of a ground pad on a PCB to which grounding clip 100 will be installed. For example, second distance 620 may be approximately equal to a distance from an edge of the PCB to a ground pad. As further described above, second angle 612 and third angle 616 may be selected based on second distance 620 and vertical distance 304. For example, second angle 612 and third angle 616 may be selected so that their sum is less than 180 degrees and vertical distance 304 is less than or equal to the thickness of a PCB. For example, second angle 612 may be approximately 90 degrees and third angle 616 may be approximately 60 degrees.

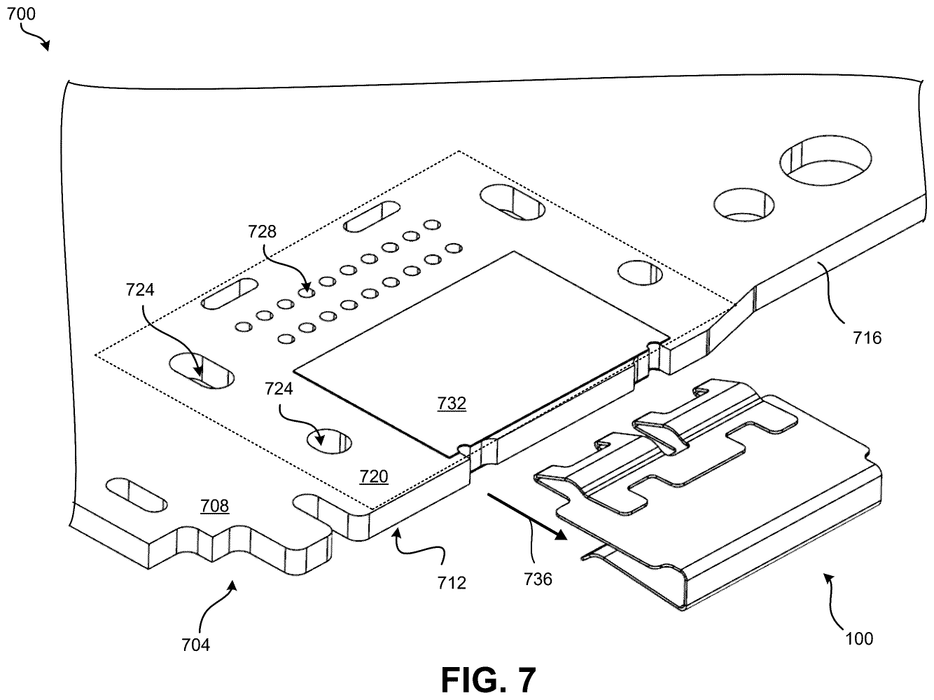

FIG. 7 illustrates an exploded view from above of an embodiment of an HDMI assembly 700. According to various embodiments of the present disclosure, assembly 700 includes grounding clip 100 as described in detail above. As illustrated, assembly 700 further includes PCB 704. Assembly 700 may further include an HDMI receptacle, as described in detail below. As further illustrated, PCB 704 includes first surface 708 and second surface 712 for component mounting and interconnections, delineated by edge 716, with layers of conductive tracks, pads, and other features embedded between first surface 708 and second surface 712.

PCB 704 may further include component mating area 720 on first surface 708 outlining the location where an electrical component, such as an HDMI receptacle, is to be installed. Within component mating area 720, PCB 704 may form one or more openings 724 and one or more through-holes 728 extending through the thickness of PCB 704 from first surface 708. The one or more openings 724 may receive one or more corresponding support structures of an electrical component to secure the electrical component to PCB 704. Each of through-holes 728 may receive a corresponding electrical pin of an electronic component and provide an electrical connection between the corresponding pin and a conductive pathway, such as a pour, trace, and/or track. While illustrated and described as through-hole connections, PCB 704 may additionally, or alternatively, include one or more surface mount pads.

As further illustrated, first surface 708 may include ground pad 732 within component mating area 720. Ground pad 732 may be a conductive area on first surface 708 that provides a direct electrical path to a ground plane of PCB 704, facilitating the safe and efficient dissipation of electrical noise, interference, and excess charge from the electronic components connected to it. For example, ground pad 732 may be electrically connected to a metal housing of an HDMI receptacle installed on first surface 708 to reduce EMI from the HDMI receptacle. EMI associated with an HDMI receptacle arises from the high-frequency signals transmitted through the HDMI interface, which can generate unwanted electromagnetic radiation that interferes with the operation of nearby electronic devices, such as wireless communication devices.

In some embodiments, ground pad 732 is electrically connected to the metal housing of an HDMI receptacle installed on first surface 708 by grounding clip 100. For example, and as described above, when installed between first surface 708 and an HDMI receptacle, grounding clip 100 may provide an electrical path from the metal housing of the HDMI receptacle through HDMI grounding portion 136 to ground pad 732 via a surface of upper jaw structure 108. Additionally, or alternatively, grounding clip 100 may provide an electrical path from the metal housing to a lower grounding pad on second surface 712, as described further below. PCB 704 and grounding clip 100 may be assembled by inserting edge 716 within opening 128 in the direction shown by arrow 736. In some embodiments, edge 716 is inserted within opening 128 of grounding clip 100 after an HDMI receptacle has been installed on first surface 708 of PCB 704.

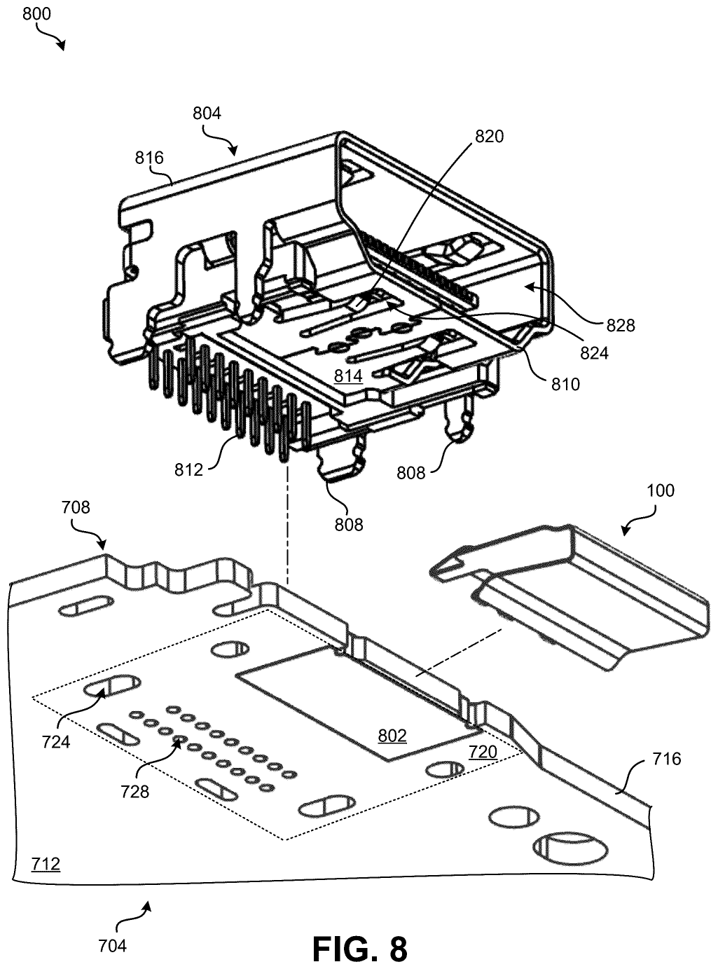

FIG. 8 illustrates an exploded view from below of an embodiment of an HDMI assembly 800. According to various embodiments of the present disclosure, assembly 700 includes grounding clip 100 and PCB 704 as described in detail above. For example, PCB 704 may form one or more openings 724 and one or more through-holes 728 extending through the thickness of PCB 704 from first surface 708 to second surface 712 within component mating area 720.

Assembly 800 further includes HDMI receptacle 804. As illustrated, HDMI receptacle 804 includes metal housing 810 and outer shielding 816. Outer shielding 816 may optionally be provided to further reduce EMI around the surfaces of HDMI receptacle 804 that are not facing PCB 704. Outer shielding 816 and metal housing 810 may be laser welded to each other. As illustrated, outer shielding 816 includes support structures 808. As described above, support structures 808 may be inserted into openings 724 of PCB 704 to secure outer shielding 816 and/or HDMI receptacle 804 to PCB 704. Metal housing 810 of HDMI receptacle 804 includes pins 812 extending away from HDMI receptacle 804 in approximately the same direction. Pins 812 may be inserted into through-holes 728 to provide an electrical connection between each pin and a corresponding conductive pathway within PCB 704.

As further illustrated, metal housing 810 may include exterior surface 814. Exterior surface 814 may include a portion of metal housing 810 opposite first surface 708 when HDMI receptacle 804 is installed on, or otherwise mounted to, first surface 708 of PCB 704. In some embodiments, a grounding pad of PCB 704, such as ground pad 732, is electrically connected to metal housing 810 at exterior surface 814 by grounding clip 100. For example, and as described above, when installed between first surface 708 and HDMI receptacle 804, grounding clip 100 may provide an electrical path from metal housing 810 through HDMI grounding portion 136 to ground pad 732 via a surface of upper jaw structure 108.

Additionally, or alternatively, grounding clip 100 may provide a continuous electrical connection between metal housing 810 and a ground plane of PCB 704 via lower grounding pad 802 on second surface 712. Lower grounding pad 802 may be a conductive area on second surface 712 that provides a direct electrical path to a ground plane of PCB 704, facilitating the safe and efficient dissipation of electrical noise, interference, and excess charge from HDMI receptacle 804.

As illustrated, metal housing 810 of HDMI receptacle 804 forms spring fingers 820 surrounded by openings 824 through exterior surface 814 of metal housing 810. Spring fingers 820 may be deformed, shaped, or otherwise pressed into interior space 828 of HDMI receptacle 804 formed by metal housing 810 such that spring fingers 820 are depressed toward first surface 708, or away from interior space 828, by an HDMI plug inserted within interior space 828 of HDMI receptacle 804. As described above, the edge of prong structure 116 may form one or more cutouts 140 to allow spring fingers 820 to be depressed toward first surface 708.

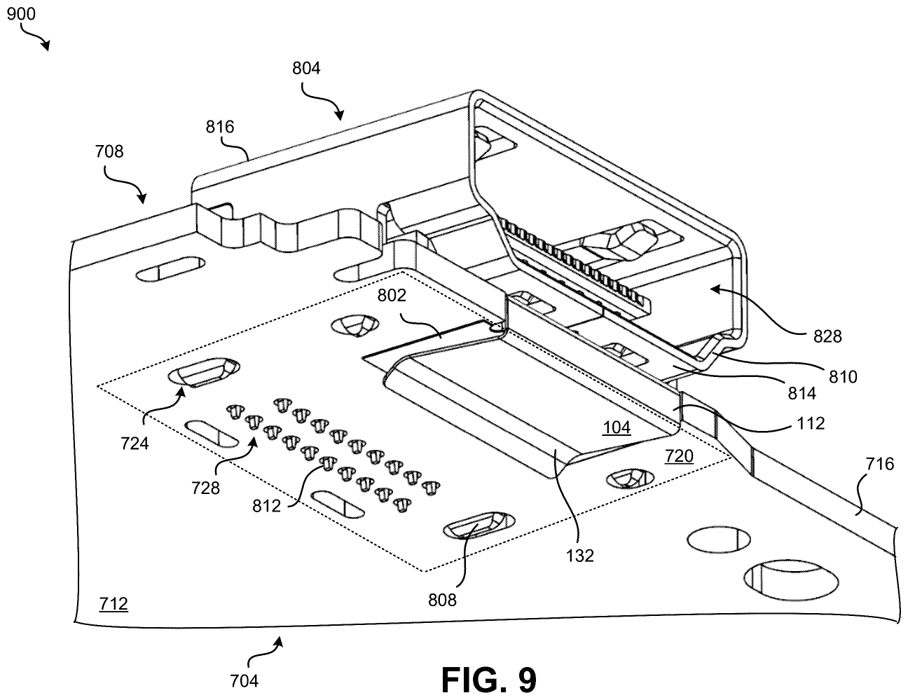

FIG. 9 illustrates an assembled view from below of an embodiment of an HDMI assembly 900. According to various embodiments of the present disclosure, assembly 900 includes grounding clip 100, PCB 704, and HDMI receptacle 804 as described in detail above. As illustrated in FIG. 9, HDMI receptacle 804 is installed on, or otherwise mounted to, first surface 708 of PCB 704. As further illustrated, an upper portion of grounding clip 100 (e.g., including upper jaw structure 108, expansion hinge 120, and prong structure 116) is inserted between first surface 708 of PCB 704 and exterior surface 814 of HDMI receptacle 804, while edge 716 of PCB 704 is inserted within opening 128 formed by a lower portion of grounding clip 100 (e.g., including lower jaw structure 104, upper jaw structure 108, and compression hinge 112).

As described above, grounding clip 100 may be maintained in place by a compressive force from compression hinge 112 that clamps PCB 704 within opening 128. Grounding clip 100 may be further maintained in place by an expansive force from an expansion hinge (e.g., expansion hinge 120) that acts to wedge the upper portion of grounding clip 100 between first surface 708 of PCB 704 and exterior surface 814 of HDMI receptacle 804. Grounding clip 100 may provide a continuous electrical connection between metal housing 810 of HDMI receptacle 804 and a ground plane of PCB 704 via one or more grounding pads on first surface 708 and/or second surface 712 of PCB 704. By providing a direct electrical path between metal housing 810 and a ground plane of PCB 704, grounding clip 100 may facilitate the safe and efficient dissipation of electrical noise, interference, and excess charge from HDMI receptacle 804.

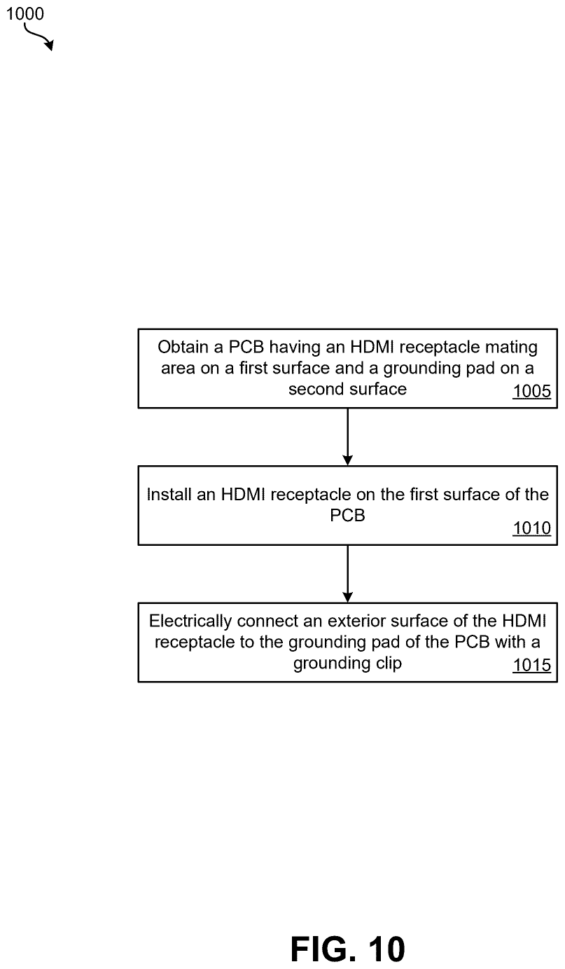

FIG. 10 illustrates a flowchart of an embodiment of a method 1000 for manufacturing a video device with reduced electromagnetic interference. Method 1000 includes step 1005 that includes obtaining a PCB having an HDMI receptacle mating area on a first surface and a grounding pad on a second surface opposite the first surface. The PCB may include any of the embodiments of the PCB 704 described in detail above. Step 1010 includes installing an HDMI receptacle on the first surface of the PCB. The HDMI receptacle may include any of the embodiments of HDMI receptacle 804 described in detail above. For example, the HDMI receptacle may include an exterior surface opposite the first surface of the PCB.

Step 1015 includes electrically connecting the exterior surface of the HDMI receptacle to the grounding pad of the PCB with a grounding clip. The grounding clip may include any of the embodiments of grounding clip 100 described in detail above. For example, the grounding clip may include: a lower jaw structure; an upper jaw structure opposite the lower jaw structure; a compression hinge that connects the lower jaw structure to the upper jaw structure; a prong structure; and an expansion hinge that connects the prong structure to the upper jaw structure opposite the compression hinge.

As further described above, electrically connecting the exterior surface of the HDMI receptacle to the grounding pad of the PCB may include inserting the edge of the PCB between the lower jaw structure and the upper jaw structure of the grounding clip, and inserting the upper jaw structure, the prong structure, and the expansion hinge between the first surface of the PCB and the exterior surface of the HDMI receptacle. Once assembled, the compression hinge may clamp the PCB between the lower jaw structure at the grounding pad and the upper jaw structure at the HDMI receptacle mating area, and the expansion hinge may press the prong structure against the exterior surface of the HDMI receptacle to provide the electrical connection.

It should be noted that the methods, systems, and devices discussed above are intended merely to be examples. It must be stressed that various embodiments may omit, substitute, or add various procedures or components as appropriate. For instance, it should be appreciated that, in alternative embodiments, the methods may be performed in an order different from that described, and that various steps may be added, omitted, or combined. Also, features described with respect to certain embodiments may be combined in various other embodiments. Different aspects and elements of the embodiments may be combined in a similar manner. Also, it should be emphasized that technology evolves and, thus, many of the elements are examples and should not be interpreted to limit the scope of the invention.

Specific details are given in the description to provide a thorough understanding of the embodiments. However, it will be understood by one of ordinary skill in the art that the embodiments may be practiced without these specific details. For example, well-known, processes, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing embodiments of the invention. Various changes may be made in the function and arrangement of elements without departing from the spirit and scope of the invention.

Also, it is noted that the embodiments may be described as a process which is depicted as a flow diagram or block diagram. Although each may describe the operations as a sequential process, many of the operations can be performed in parallel or concurrently. In addition, the order of the operations may be rearranged. A process may have additional steps not included in the figure.

Having described several embodiments, it will be recognized by those of skill in the art that various modifications, alternative constructions, and equivalents may be used without departing from the spirit of the invention. For example, the above elements may merely be a component of a larger system, wherein other rules may take precedence over or otherwise modify the application of the invention. Also, a number of steps may be undertaken before, during, or after the above elements are considered. Accordingly, the above description should not be taken as limiting the scope of the invention.

What is claimed is:

1. A high-definition multimedia interface (HDMI) assembly comprising:
a printed circuit board (PCB) comprising a first surface, a second surface opposite the first surface, an HDMI receptacle mating area on the first surface at an edge of the PCB, and a grounding pad on the second surface opposite the HDMI receptacle mating area;
an HDMI receptacle installed on the first surface of the PCB at the HDMI receptacle mating area and having an exterior surface opposite the first surface of the PCB; and
a grounding clip comprising:
a lower jaw structure;
an upper jaw structure opposite the lower jaw structure;
a compression hinge that connects the lower jaw structure to the upper jaw structure and clamps the PCB between the lower jaw structure at the grounding pad and the upper jaw structure at the HDMI receptacle mating area;
a prong structure; and
an expansion hinge that connects the prong structure to the upper jaw structure opposite the compression hinge and presses the prong structure against the exterior surface of the HDMI receptacle.

2. The HDMI assembly of claim 1, wherein the grounding clip is a single piece of conductive material that forms each of the lower jaw structure, the compression hinge, the upper jaw structure, the expansion hinge, and the prong structure.

3. The HDMI assembly of claim 2, wherein the single piece of conductive material comprises a planar strip of metal.

4. The HDMI assembly of claim 1, wherein:
the compression hinge separates a first end of the upper jaw structure from a first end of the lower jaw structure at the compression hinge by a first distance; and
the upper jaw structure and the lower jaw structure extend from the compression hinge toward each other in a first direction so that a second end of the lower jaw structure opposite the first end of the lower jaw structure is separated from a second end of the upper jaw structure opposite the first end of the upper jaw structure by a second distance that is less than the first distance.

5. The HDMI assembly of claim 4, wherein the first end of the upper jaw structure connects with a first end of the compression hinge at a right angle and the first end of the lower jaw structure connects with a second end of the compression hinge opposite the first end of the compression hinge.

6. The HDMI assembly of claim 4, wherein the expansion hinge connects the prong structure to the upper jaw structure at an acute angle.

7. The HDMI assembly of claim 1, wherein the grounding clip provides a continuous electrical connection between the exterior surface of the HDMI receptable and a ground plane of the PCB via the grounding pad on the second surface of the PCB.

8. The HDMI assembly of claim 1, wherein:
the HDMI receptacle forms an opening through the exterior surface surrounding a spring finger that is depressed toward the first surface of the PCB by an HDMI plug inserted within an interior space formed by the HDMI receptacle; and
the prong structure comprises a cutout at an end of the prong structure opposite the expansion hinge, the cutout being aligned with the opening through the exterior surface of the HDMI receptacle.

9. The HDMI assembly of claim 1, wherein:
the PCB further comprises a secondary grounding pad on the first surface of the PCB within the HDMI receptacle mating area; and
a force applied to the prong structure toward the upper jaw structure causes the expansion hinge to press the upper jaw structure against the secondary grounding pad.

10. A method of manufacturing a video device with reduced electromagnetic interference, comprising:
obtaining a printed circuit board (PCB) comprising a first surface, a second surface opposite the first surface, an HDMI receptacle mating area on the first surface at an edge of the PCB, and a grounding pad on the second surface opposite the HDMI receptacle mating area;
installing an HDMI receptacle on the first surface of the PCB at the HDMI receptacle mating area, wherein the HDMI receptacle comprises an exterior surface opposite the first surface of the PCB; and
electrically connecting the exterior surface of the HDMI receptacle to the grounding pad of the PCB with a grounding clip by:
inserting the edge of the PCB between a lower jaw structure of the grounding clip and an upper jaw structure of the grounding clip opposite the lower jaw structure so that the second surface of the PCB faces the lower jaw structure and the first surface of the PCB faces the upper jaw structure, wherein a compression hinge connecting the lower jaw structure to the upper jaw structure clamps the PCB between the lower jaw structure at the grounding pad and the upper jaw structure at the HDMI receptacle mating area; and
inserting, between the first surface of the PCB and the exterior surface of the HDMI receptacle, the upper jaw structure, a prong structure of the grounding clip, and an expansion hinge of the grounding clip that connects the prong structure to the upper jaw structure opposite the compression hinge and presses the prong structure against the exterior surface of the HDMI receptacle.

11. The method of manufacturing a circuit board for a video device of claim 10, wherein the grounding clip is a single piece of conductive material that forms each of the lower jaw structure, the compression hinge, the upper jaw structure, the expansion hinge, and the prong structure.

12. The method of manufacturing a circuit board for a video device of claim 11, wherein the single piece of conductive material comprises a planar strip of metal.

13. The method of manufacturing a circuit board for a video device of claim 12, wherein the planar strip of metal comprises a first end and a second end separated by a middle portion and the method further comprises forming the grounding clip by:
bending the first end of the planar strip of metal in a first direction with respect to the middle portion by at least 180 degrees to form the compression hinge; and
bending the second end of the planar strip of metal in a second direction opposite the first direction by at least 90 degrees and less than 180 degrees to form the expansion hinge.

14. The method of manufacturing a circuit board for a video device of claim 10, wherein the edge of the PCB is inserted between the lower jaw structure and the upper jaw structure simultaneously with insertion of the upper jaw structure, the prong structure, and the expansion hinge between the first surface of the PCB and the exterior surface of the HDMI receptacle.

15. The method of manufacturing a circuit board for a video device of claim 10, wherein the grounding clip provides a continuous electrical connection between the exterior surface of the HDMI receptable and a ground plane of the PCB via the grounding pad on the second surface of the PCB.

16. The method of manufacturing a circuit board for a video device of claim 10, wherein:
the HDMI receptacle forms an opening through the exterior surface surrounding a spring finger that is depressed toward the first surface of the PCB by an HDMI plug inserted within an interior space formed by the HDMI receptacle;
the prong structure comprises a cutout at an end of the prong structure opposite the expansion hinge; and
the upper jaw structure, the prong structure, and the expansion hinge are inserted between the first surface of the PCB and the exterior surface of the HDMI receptacle until the cutout is aligned with the opening through the exterior surface of the HDMI receptacle.

17. The method of manufacturing a circuit board for a video device of claim 10, wherein:
the PCB further comprises a secondary grounding pad on the first surface of the PCB within the HDMI receptacle mating area; and
a force applied to the prong structure toward the upper jaw structure by the exterior surface of the HDMI receptacle causes the expansion hinge to press the upper jaw structure against the secondary grounding pad.

18. A clip for increased grounding of a high-definition multimedia interface (HDMI) receptacle, comprising:
a lower jaw structure;
an upper jaw structure opposite the lower jaw structure;
a compression hinge that connects the lower jaw structure to the upper jaw structure and clamps a PCB between the lower jaw structure at a grounding pad on a first surface of the PCB, and the upper jaw structure at an HDMI receptacle mating area on a second surface of the PCB opposite the first surface;
a prong structure; and
an expansion hinge that connects the prong structure to the upper jaw structure opposite the compression hinge and presses the prong structure against an exterior surface of an HDMI receptacle installed on the first surface of the PCB.

19. The clip for increased grounding of an HDMI receptacle of claim 18, wherein the lower jaw structure, the compression hinge, the upper jaw structure, the expansion hinge, and the prong structure are a single piece of planar conductive material.

20. The clip for increased grounding of an HDMI receptacle of claim 18, wherein:
the compression hinge separates a first end of the upper jaw structure from a first end of the lower jaw structure at the compression hinge by a first distance;
the upper jaw structure and the lower jaw structure extend from the compression hinge toward each other in a first direction so that a second end of the lower jaw structure opposite the first end of the lower jaw structure is separated from a second end of the upper jaw structure opposite the first end of the upper jaw structure by a second distance that is less than the first distance; and
the expansion hinge connects the prong structure to the upper jaw structure at an acute angle opening in a second direction opposite the first direction.
